(19) United States
(12) Patent Application Publication
(10) Pub. No.: US 2026/0183883 A1
(43) Pub. Date: Jul. 2, 2026

(54) ELECTROSTATIC CHUCK WITH A LIGHT HEATING STRUCTURE

(71) Applicant: VM Inc., Icheon-si (KR)

(72) Inventors: Hwi Gon JANG, Yongin-si (KR); Woo Hyung CHOI, Seongnam-si (KR); Sung Kyun JUNG, Suwon-si (KR); Sung Hwan PARK, Suwon-si (KR); Jin Myeong LEE, Yongin-si (KR)

(21) Appl. No.: 19/435,361

(22) Filed: Dec. 29, 2025

(30) Foreign Application Priority Data
Dec. 31, 2024 (KR) 10-2024-0201563

(51) Int. Cl. B23Q 11/14; B23Q 3/15; H02N 13/00

(52) U.S. Cl. CPC B23Q 11/143; B23Q 3/15; H02N 13/00

(57) ABSTRACT

Provided is an electrostatic chuck with a light heating structure. The electrostatic chuck with a light heating structure comprises a body block 11; a dielectric layer 12 coupled to an upper surface of the body block 11; a heater 13 for heating the dielectric layer 12; and a light emitting module 14 for inducing a light to a lower surface of the dielectric layer 12 and heating the dielectric layer 12.

### BACKGROUND OF THE INVENTION

### Field of the Invention

The present invention relates to an electrostatic chuck with a light heating structure, in particular, the electrostatic chuck whose temperature can be controlled by introducing a light such as a laser light or a LED light to a dielectric layer.

### Description of the Related Art

An electrostatic chuck fixing a wafer or a substrate on an upper surface with an electrostatic force may be used for a semiconductor process or a LCD substrate manufacturing process. The electrostatic chuck may comprise a body block, a heater and a dielectric layer, and a temperature uniformity of the electrostatic chuck is an important factor to affect a process result significantly. And as the semiconductor processing technology advances, a level required with respect to the temperature uniformity of the electrostatic chuck has become more stringent. The temperature of the electrostatic chuck may be maintained uniformly within a specified temperature range in order to obtain a process precision and uniformity. For this purpose, the electrostatic chuck may be segmented into a plurality of heating sections, and each section may be controlled independently. But as the chuck is segmented into the more sections, its design and controlling become the more complex.

A method to arrange a plurality of resistive heating rods at the aluminum body of the electrostatic chuck, to contact the rods and to heat the electrostatic chuck may be applied for controlling the temperature of the electrostatic chuck. But this method has a disadvantage that the resistive heater occupies a large volume, and various type of limitations can occur in the course of heating by the contact. Specifically, as the heating zone is more segmented for improving the temperature uniformity, the zones occupied by the resistive heater may increase, which may result in the limitation of a design of a cooing channel. And also, it has a problem that each heating zone may not be heated uniformly due to limitations depending on the contacting way and the volume change of the resistive heater for the temperature change.

And also, a method where an infrared light generated from an infrared heater may be absorbed on a silicon wafer through a dielectric layer to heat the wafer directly may be applied for controlling the temperature of the electrostatic chuck. Such method has a disadvantage that a transmittance may be different owing to the transmittances of the dielectric layer and a bonding area in the course of heating the wafer after the infrared light passes through the dielectric layer and the bonding area, and as a result the difference of the heating level may occur. And also, when the infrared is absorbed on the dielectric layer or the bonding area, unexpected heating may occur to affect the heat control. Furthermore, the method has a disadvantage that it is difficult to maintain the required temperature because it is not easy to measure the temperature of the silicon wafer within a plasma processing chamber.

Therefore, it is required to develop the technology to improve a temperature uniformity of the electrostatic chuck through a local temperature control based on the known electrostatic chuck structure, but the prior art does not discuss such technology. The present invention is intended to solve the problem of the prior art and has the following purpose.

### PURPOSE OF THE INVENTION

An object of the present invention is to provide with an electrostatic chuck with a light heating structure to induce a light such as a laser light or a LED light to a dielectric layer of an electrostatic chuck, to control a local temperature or a whole temperature of the electrostatic layer and to enhance the temperature uniformity of the electrostatic chuck

### SUMMARY OF THE INVENTION

In one embodiment of the present invention, an electrostatic chuck with a light heating structure comprises a body block; a dielectric layer coupled to an upper surface of the body block; a heater for heating the dielectric layer; and a light emitting module for inducing a light to a lower surface of the dielectric layer 12 and heating the dielectric layer.

In other embodiment of the present invention, the electrostatic chuck further comprises a light guiding passage formed at the body block

In another embodiment of the present invention, the light emitting module comprises a laser element or a LED element.

In still another embodiment of the present invention, the light emitting module is disposed at an inside or an outside of the body block.

In still another embodiment of present invention, the light emitting module comprises a board and a plurality of light elements disposed at the board.

In still another embodiment of the present invention. the light guiding passage is a guiding hole formed at the body block.

In still another embodiment of the present invention, the plurality of light elements are controlled individually.

In still another embodiment of the present invention, the light emitting module 14 heats the dielectric layer locally.

In still another embodiment of the present invention, the lower surface of the dielectric layer is made in a structure capable of absorbing a light and of converting the light into a heat energy.

### BRIEF DESCRIPTION OF THE DRAWINGS

FIG. 1 shows an embodiment of an electrostatic chuck with a light heating structure according to the present invention.

FIG. 2 shows an embodiment of an electrostatic chuck structure according to the present invention.

FIG. 3 shows an embodiment of a light emitting module for the electrostatic chuck according to the present invention.

FIG. 4 shows an embodiment of a way how the light emitting module is disposed according to the present invention.

FIG. 5 shows an embodiment of a procedure to control a temperature of the electrostatic chuck locally according to the present invention.

### DETAILED DESCRIPTION OF EXEMPLARY EMBODIMENTS

Exemplary embodiments of the present invention will be described herein below with reference to the accompanying drawings.

The electrostatic chuck with a light heating structure according to the present invention adds a light element for heating a dielectric layer to the electrostatic chuck structure having an embedded heater within the dielectric layer to enhance a temperature uniformity of the heating section by heating the dielectric layer locally. The electrostatic chuck according to the present invention has an advantage of easy maintenance and/or repair as the whole structure is made as simple and straightforward. Specifically, according to the electrostatic chuck of the present invention, the light radiated from a plurality of light elements is induced to a lower surface of the dielectric layer to heat the dielectric layer for control the temperature of the electrostatic chuck. The chuck according to the present invention is suitable for obtain the temperature uniformity of high degree required in the semiconductor industry with the industry advancement, thus prevents a defect occurrence which may be generated owing to a temperature deviation during a manufacturing process of a wafer. The chuck according to the present invention may be made as various structures or of various materials, but not limited to.

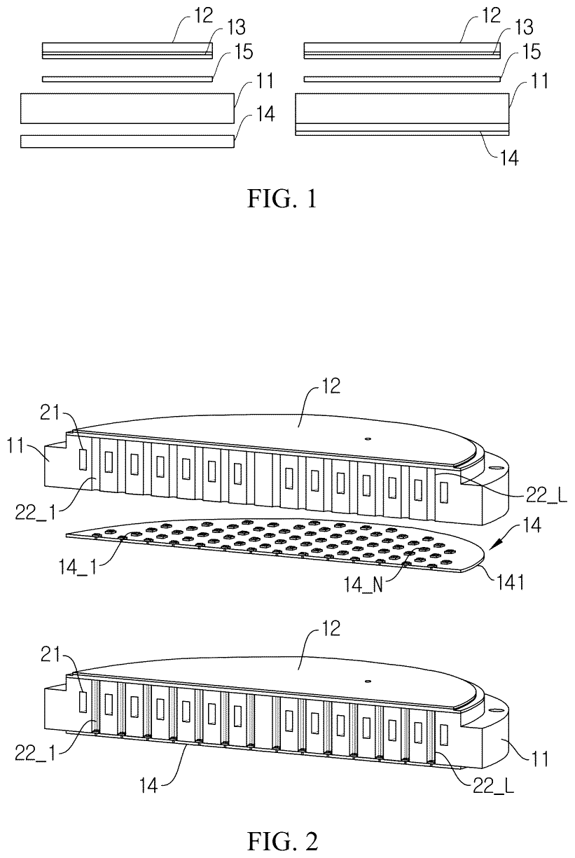

FIG. 1 shows an embodiment of an electrostatic chuck with a light heating structure according to the present invention.

Referring to FIG. 1, an electrostatic chuck with a light heating structure comprises a body block 11; a dielectric layer 12 coupled to an upper surface of the body block 11; a heater 13 for heating the dielectric layer 12; and a light emitting module 14 for inducing a light to a lower surface of the dielectric layer 12 and heating the dielectric layer 12.

The body block 11 may have an overall cylindrical shape, and be made of, for example, an aluminum material. The dielectric layer 12 with a circular plate shape may be disposed at an upper surface of the body block 12, and the dielectric layer 12 may be made of an insulating material such as a ceramic. The dielectric layer 12 may be formed in various ways, and for example, the dielectric layer 12 may be formed into a sheet to be adhered on the upper surface of the body block 11 by an adhering layer 15. The dielectric layer 12 may be heated by the heater 13, and the heater 13 may be disposed within the dielectric layer 12 in an inserted way, and for example, the heater 13 may become a resistive heating element or a plate shape of heating element. The heater 13 may be disposed in various ways between an upper part of the body block 11 and the dielectric layer 12, and the heater 13 may become a first heater heating the upper surface of the dielectric layer 12 or a substrate fixed at the upper part of the dielectric layer 12. The substrate such as a wafer may be fixed at the upper surface of the dielectric layer 12 by an electrostatic force, and the dielectric layer 12 may have a structure suitable for fixing the substrate. The electrostatic chuck may comprise a lift pin to raise the substrate, or various components similar to the lift pin, and the present invention is not limited to such configuration or other configuration.

According to one embodiment of the present invention, the electrostatic comprise the light emitting module 14, and a light emitted from the light emitting module 14 is emitted to be induced to the lower surface of the dielectric layer 12, and the light heats the dielectric layer 12 and the substrate fixed at the upper part of the dielectric layer 12. The light emitting module 14 may comprise a plurality of light emitting elements capable of emitting the light, the light emitted from the light emitting elements may be induced to the lower surface of the dielectric layer 12 to be converted into heat energy, and may heat the dielectric layer 12. The light emitted from the light emitting module 14 may be incident to the lower surface of the dielectric layer 12, and the light may have a wavelength band to be converted into heat, for example, the light may have 700 to 1,500 nm of wavelength band. And also, the light may have infrared wavelength band, far infrared wavelength band or near infrared wavelength band, but not limited to.

The light emitting module 14 may be within the body block 11 or below the body block 11. In such case, it is necessary for the light to be induced to the dielectric layer 12 via the body block 11. A light guiding passage may be formed at the body block 11 for guiding the light through an inside of the body block 11. The light guiding passage may have, for example, a penetrating hole structure penetrating the body block 11 or may become a light fiber passage formed in a way to penetrating the body block, but not limited to. Various guiding passages may be formed for inducing the light emitted from the light emitting module 14 to the lower surface of the dielectric layer 12, but not limited to.

According to one embodiment of the present invention, the lower surface of the dielectric layer 12 may be made in a structure capable of absorbing the light and converting the absorbed light into a heat, for example, the dielectric layer 12 may be coated with a silicone or a light absorbing material similar to it. The lower surface of the dielectric layer 12 may be coated with a material to absorb the wavelength band of light emitted from the light emitting module 14, or the lower surface of the dielectric layer 12 may be coated with a black ink capable of absorbing all wavelength band of light. The lower surface of the dielectric layer 12 may be made of various materials to absorb a specified wavelength band of light or all wavelength band of light and to convert the absorbed light into heat energy, but not limited to.

According to one embodiment of the present invention, the dielectric layer 12 may be heated locally. The dielectric layer 12 may have an all-over circular plate shape, and the entire dielectric layer 13 may be heated with the heater 13 disposed within the dielectric layer 12, and a temperature deviation may occur in the course of heating by such heater 13. The light emitting module 14 may induce the light to a portion having a temperature relatively lower than the other portion to heat the dielectric layer 12 locally. Thereby, the temperature uniformity over the entire dielectric layer 12 may be obtained. The light emitting module 14 may have a proper structure capable of heating the dielectric layer 12 locally. For example, a plurality of light emitting elements may be disposed on the circular plate corresponding to the dielectric layer 12, and an operation of each light emitting element may be controlled independently to heat some portions of the dielectric layer 12 locally. The light emitting module 14 may have various structures capable of heating the dielectric layer 12, but not limited to.

FIG. 2 shows an embodiment of an electrostatic chuck structure according to the present invention.

Referring to FIG. 2, the light emitting module 14 may comprise a board 141 and a plurality of light elements 14_1 to 14_N disposed at the board 141. The board 141 may have an overall circular plate shape corresponding to the dielectric layer 12. The plurality of elements 14_1 to 14_N may be arranged at the board 141 uniformly. The board 141 may become, for example, a printed circuit board, and the plurality of light elements 14_1 to 14_N may become laser elements such as a laser diode or LED elements, but not limited to. The laser element may become various kinds of laser such as a gas laser, a solid state laser, a liquid laser or a semiconductor laser, but not limited to. The element controller may be installed to control an operation of each light element 14_1 to 14_N.

A circular plate shape of light emitting module 14 may be disposed below the body block 11 with a cylindrical shape. In this case, when the light emitting module 14 is disposed below the body block 11, it is necessary for the light guiding passage to be formed. While a cooling passage 21 extending in a horizontal direction may be formed in order that the cooling water may flow at the body block 11, a plurality of guiding holes 22_1 to 22_L extending in a direction vertical to the body block 11 may be formed and each guiding hole 22_1 to 22_L may be extended in a way to avoid the cooling passage 21. And also, each guiding hole 22_1 to 22_L may be vacuum sealed and have a proper shape to induce each light element 14_1 to 14_N to the lower surface of the dielectric layer 12. The plurality of light elements 14_1 to 14_N may be arranged in various ways, but not limited to.

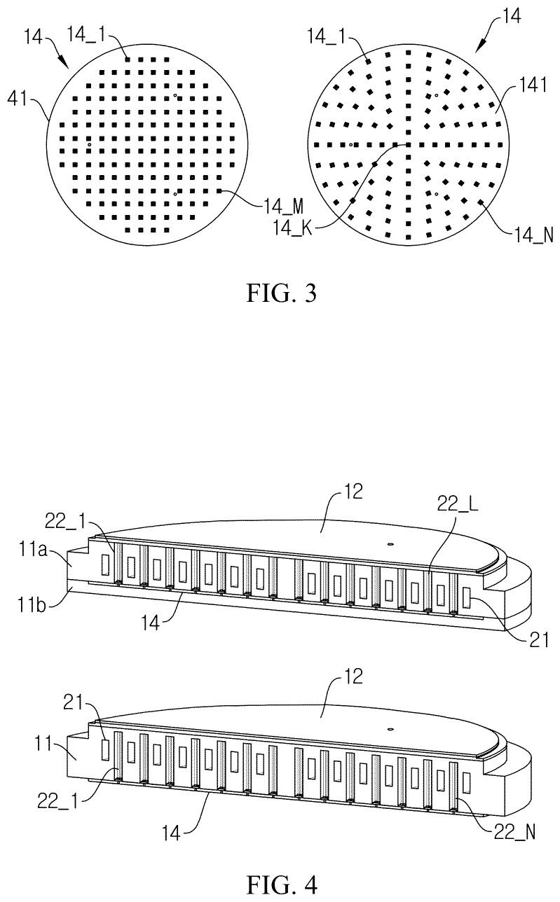

FIG. 3 shows an embodiment of a light emitting module for the electrostatic chuck according to the present invention.

Referring the left part of FIG. 3, the board 141 may have a circular plate shape, and the plurality of light elements 14_1 to 14_M may be arranged on the upper surface of the board 141 in a lattice shape. Specifically, the plurality of light elements may be arranged along one diameter of the board 141 and along a plurality of chords parallel to one diameter. Referring to the right of FIG. 3, the plurality of light elements 14_1 to 14_N may be arranged at the board 141 along circles with different diameters. Specifically, one light element, for example, 14_K may be displaced at an upper surface center of the board 141, and the plurality of light elements 14_1 to 14_N may be arranged along the plurality of circles with different diameters based on the center. The plurality of light elements 14_1 to 14_N may be arranged on the upper surface of the board in a uniformly way or in an unevenly way, but not limited to.

FIG. 4 shows an embodiment of a way how the light emitting module is disposed according to the present invention.

Referring to FIG. 4, the light emitting module 14 may be disposed at an inside or outside of the body block 14. According to the present invention, the heater of the electrostatic chuck may comprise a first heater and a second heater. The first heater may become a resistive heater embedded within the dielectric layer 12 and control the entire temperature of the dielectric layer 12. For example, the heating section may be divided into two areas or four areas, and the first heater may heat the divided heating areas of the dielectric layer 12. Lift pins, helium holes, heating terminals or similar components for operating the electrostatic chuck may be arranged within the electrostatic chuck, and as a result, a local temperature difference may occur because such components have to be avoided in the course of designing. The second heater may be installed for compensating such local temperature difference, and the second heater may become the light emitting module 14 according to the present invention. The light emitting module 14 may use laser elements to heat the dielectric layer directly through the guiding holes 22_1 to 22_N formed at the body block 11. The laser elements may have a function to compensate the local temperature difference that it is difficult to control with the first heater, and thereby, the entire temperature uniformity of the dielectric layer 12 may be enhanced. The laser element has an advantage that it can generate a large amount of heat for its small size and has a high degree of straight emitting property to heat the dielectric layer 12 accurately in case of being located below the electrostatic chuck. And also, the miniaturized laser element facilitates the design of the cooling passage 21. And also, the miniaturized laser element eliminates a need to consider a contacting efficiency or a thermal expansion issue that should be considered in case of the resistive heater corresponding to the first heater, and thereby, it has some advantages in view of structure.

Optionally as shown in the lower part of FIG. 4, the light emitting module 14 may be installed outside the lower surface of the body block 11, and thereby the light emitting module 14 may be removable easily. Accordingly, it has an advantage that the light emitting module 14 can be maintained or repaired by replacing the light emitting elements or the board. As shown in the upper part of FIG. 4, the light emitting module 14 may be placed inside the body block 11. In this way, the body block 11 for disposing the light emitting module 14 inside the body block 11 may comprise a base block 11a and a lower covering block 11b. A groove for arranging the light emitting module 14 may be formed at the base block 11a or the lower covering block 11b, and the lower covering block 11b may be coupled to the base block 11a in various ways. The light emitting module 14 may be placed at various positions of the electrostatic chuck to induce the light to the lower surface of the dielectric layer 12, but not limited. to.

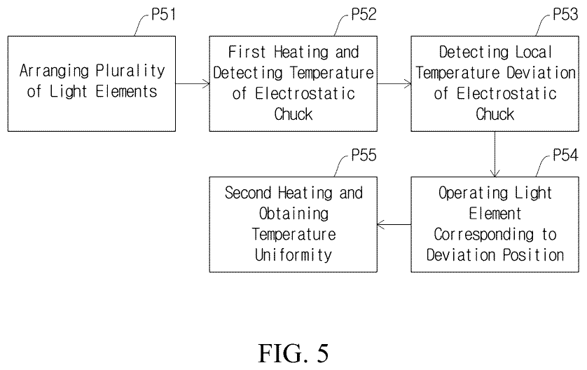

FIG. 5 shows an embodiment of a procedure to control a temperature of the electrostatic chuck locally according to the present invention.

Referring to FIG. 5, a plurality of light elements may be arranged for controlling an electrostatic chuck locally (step P51), and the plurality of light elements may become a plurality of laser elements. The plurality of light elements may be arranged on a board with a circular plate shape, and an operation of each light element may be controlled individually. The board on which the light elements are arranged may be placed below the electrostatic chuck, and a light emitted from the plurality of light elements can heat a dielectric layer disposed in the upper part of the electrostatic chuck through a suitable guiding passage. The dielectric layer may be heated by a first heater disposed at the dielectric layer during a process for a substrate such as a wafer, and a temperature of the electrostatic chuck may be detected (step P52). A temperature gradient along a horizontal direction of the electrostatic chuck may be detected, and a local temperature deviation of the electrostatic chuck may be detected (step P53). A local temperature deviation may occur, and for example, a portion having a local lower temperature may be generated. When the temperature deviation occurs, the light elements arranged at a position corresponding to the portion having the lower temperature may activate (step P54). Thereby, the corresponding portion may be heated secondarily, and a temperature uniformity over an entire electrostatic chuck can be obtained (step P55). A local temperature control of the electrostatic chuck may be performed by the light elements such as the laser elements in various ways, but not limited to.

While the present invention has been particularly shown and described with reference to exemplary embodiments thereof, it will be understood by those skilled in the art that various changes in form and details may be made therein without departing from the spirit and scope of the present invention as defined by the appended claims.

What is claimed is:

1. An electrostatic chuck with a light heating structure comprising:
a body block;
a dielectric layer coupled to an upper surface of the body block;
a heater for heating the dielectric layer; and
a light emitting module for inducing a light to a lower surface of the dielectric layer and heating the dielectric layer.

2. The electrostatic chuck according to claim 1, wherein the electrostatic chuck further comprises a light guiding passage formed at the body block.

3. The electrostatic chuck according to claim 1, wherein the light emitting module comprises a laser element or a LED element.

4. The electrostatic chuck according to claim 1, wherein the light emitting module is disposed at an inside or an outside of the body block.

5. The electrostatic chuck according to claim 1, wherein the light emitting module comprises a board and a plurality of light elements disposed at the board.

6. The electrostatic chuck according to claim 2, wherein the light guiding passage is a guiding hole formed at the body block.

7. The electrostatic chuck according to claim 5, wherein the plurality of light elements are controlled individually.

8. The electrostatic chuck according to claim 1, wherein the light emitting module heats the dielectric layer locally.

9. The electrostatic chuck according to claim 1, wherein the lower surface of the dielectric layer is made in a structure capable of absorbing a light and of converting the light into a heat energy.
